(19) United States
(12) Patent Application Publication
(10) Pub. No.: US 2007/0133640 A1
(43) Pub. Date: Jun. 14, 2007

(54) Vertical external cavity surface emitting laser with pump beam reflector

(75) Inventor: Ki-sung Kim, Hwaseong-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/541,540

(22) Filed: Oct. 3, 2006

(30) Foreign Application Priority Data
Dec. 8, 2005 (KR) 10-2005-0119251

(51) Int. Cl. H01S 3/10; H01S 5/00

(52) U.S. Cl. 372/50.124; 372/22

(57) ABSTRACT

Provided is a vertical external cavity surface emitting laser (VECSEL). The VECSEL includes: a semiconductor chip including an active layer emitting a beam having a predetermined wavelength and a reflection layer reflecting the beam generated from the active layer to the outside of the active layer; an external mirror that faces the active layer and repeatedly reflects a beam emitted from the active layer to the reflection layer to amplify the beam and output the amplified beam to the outside; a pump energy supplying a pumping energy to excite the active layer; a second harmonic generation (SHG) device that is disposed between the semiconductor chip and the external mirror and converts the wavelength of the beam emitted from the active layer; and a semiconductor filter or dielectric filter coupled with the SHG device. The VECSEL includes a semiconductor filter or dielectric filter which can easily select a wavelength and can be easily manufactured, and thus can be high light conversion efficiency, is simple, and low manufacturing cost.

### CROSS-REFERENCE TO RELATED PATENT APPLICATION

Priority is claimed to Korean Patent Application No. 10-2005-0119251, filed on Dec. 8, 2005 in the Korean Intellectual Property Office, the disclosure of which is incorporated herein in its entirety by reference.

### BACKGROUND OF THE DISCLOSURE

1. Field of the Disclosure

The present disclosure relates to a vertical external cavity surface emitting laser (VECSEL), and more particularly, to a VECSEL with a simple structure in certain embodiments that can be manufactured at low cost.

2. Description of the Related Art

A vertical cavity surface emitting laser (VCSEL), in which a beam is emitted vertically relative to a substrate, oscillates light in a single longitudinal mode of a very narrow spectrum, emits a beam having a small radiation angle, and thus has good coupling efficiency. A VCSEL can be easily integrated with other devices due to its structure, and can be used as a pumping light source. However, a conventional VCSEL cannot easily perform single transverse mode oscillation because the VCSEL operates in multiple modes due to a thermal lens effect caused by the increase of light output, and the single transverse mode output is also low.

A vertical external cavity surface emitting laser (VECSEL) is a high light output laser with the above-described advantages of the VCSEL. The VECSEL has an external mirror instead of an upper mirror to increase a gain region, and can thus output several to dozens of watts of light.

FIG. 1 is a schematic view of a conventional VECSEL 10. The illustrated VECSEL 10 is a front optical pumping laser including a pumping laser 15 that supplies a pumping beam λ₁ and is located in front of a semiconductor chip 13. The semiconductor chip 13 includes a Distributed Bragg Reflector 11 and an active layer 12 sequentially formed on a heat sink 14. An external mirror 20 is disposed a predetermined distance from the semiconductor chip 13 and faces the semiconductor chip 13. A lens 16 focusing the pumping beam emitted from the pump laser 15 is disposed between the pump laser 15 and the semiconductor chip 13.

A second harmonic generation (SHG) device 18 and a birefringence filter 17 to increase the second harmonic generation are disposed between the activation layer 12 and the external mirror 20. The birefringence filter 17 filters light of a single narrow wavelength band, and thus increases the light conversion efficiency.

The active layer 12 may be a multiple quantum well layer having a resonant periodic gain (RPG) structure, which is excited by the pumping beam A and emits a beam having a predetermined wavelength λ₂. The pump laser 15 emits light at a wavelength λ₁, which is shorter than the wavelength λ₂ of the light generated by the active layer 12, to excite the active layer 12.

In the above described configuration, when the pumping laser 15 emits the pumping beam with the wavelength λ₁ to impinge on the active layer 12, the active layer 12 is excited and emits the beam at the wavelength λ₂. The beam resonates by being repeatedly reflected in the resonant cavity formed by the DBR layer 11 and the external mirror 20. A portion of the beam amplified in the resonant cavity is emitted to the outside through the external mirror 20. The beam emitted from the active layer 12, which is a multiple longitudinal mode beam, is filtered by the birefringence filter 17 to obtain a single mode beam having a narrow line width. For example, a beam in the infrared ray range is converted into a beam in the visible light range and output.

When using the birefringence filter 17 to select the polarization and wavelength of the resonating light, the birefringence filter 17 needs to be installed at a regular angle with respect to the main path of the light, and thus additional space to accommodate the birefringence filter 17 is needed. Also, the birefringence filter 17 is expensive, the manufacturing process thereof is complicated, and the birefringence filter 17 needs to be arranged according to the polarization, which requires a jig. Thus, the overall volume of the VECSEL increases. Furthermore, because the SHG crystal 18 is sensitive to temperature, the temperature needs to be controlled. Since the temperature of the birefringence filter 17 needs to be controlled according to the temperature of the SHG crystal 18, temperature control becomes complicated.

### SUMMARY OF THE DISCLOSURE

The present disclosure provides a vertical external cavity surface emitting laser (VECSEL) which in certain embodiments can be manufactured at low costs and has a simple structure for easy alignment.

According to an aspect of the present disclosure, there is provided a vertical external cavity surface emitting laser (VECSEL) comprising: a semiconductor chip including an active layer emitting a beam having a predetermined wavelength and a reflection layer reflecting the beam generated in the active layer to the outside of the active layer; an external mirror that faces the active layer and repeatedly reflects a beam emitted from the active layer to the reflection layer to amplify the beam and output the amplified beam to the outside; a pump laser supplying a pumping beam to excite the active layer; a second harmonic generation (SHG) device that is disposed between the semiconductor chip and the external mirror and converts the wavelength of the beam emitted from the active layer; and a semiconductor filter coupled with the SHG device.

According to another aspect of the present disclosure, there is provided a VECSEL comprising: a semiconductor chip including an active layer emitting a beam having a predetermined wavelength and a reflection layer reflecting the beam generated from the active layer to the outside of the active layer; an external mirror that faces the active layer and repeatedly reflects a beam emitted from the active layer to the reflection layer to amplify the beam and output the amplified beam to the outside; a pump laser supplying a pumping beam to excite the active layer; a second harmonic generation (SHG) device that is disposed between the semiconductor chip and the external mirror and converts the wavelength of the beam emitted from the active layer; and a dielectric filter coupled with the SHG device.

The reflection layer may be a multi-layered Distributed Bragg Reflector comprising sets of two semiconductor layers having different refractive indexes repeatedly alternately stacked.

The thickness of each of the semiconductor layers may be one fourth of the wavelength of the emitted beam.

The active layer may include a plurality of quantum well layers generating a beam and each of the quantum well layer is disposed in an anti-node of a standing wave which is generated by the beam resonating between the external mirror and the reflection mirror.

The semiconductor filter may have a transmittance of 30% or greater and a non-zero line width of 10 nm or less.

The dielectric filter may have a transmittance of 30% or greater at a selected wavelength and a non-zero line width of 10 nm or less.

The first semiconductor layer is an AlAs layer having a relatively low refractive index and the second semiconductor layer is an Al_{0.2}GaAs layer having a relatively high refractive index.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of a conventional vertical external cavity surface emitting laser (VECSEL);

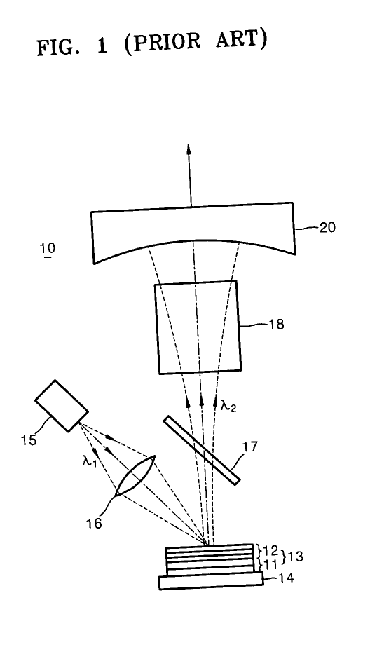

FIG. 2 is a schematic diagram of a VECSEL according to an embodiment of the present disclosure;

FIG. 3 is a cross-sectional view of a semiconductor filter used in the VECSEL of FIG. 2; and

FIG. 4 is a transmittance spectrum obtained by simulating the VECSEL of FIG. 2 using the semiconductor filter of FIG. 3.

### DETAILED DESCRIPTION OF THE DISCLOSURE

The present invention will now be described more fully with reference to the accompanying drawings, in which exemplary embodiments of the invention are shown. In the drawings, the thicknesses of layers and regions are exaggerated for clarity.

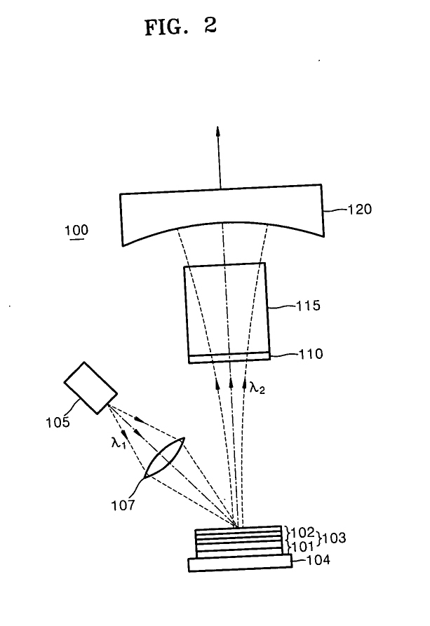

FIG. 2 is a schematic diagram of a vertical external cavity surface emitting laser (VECSEL) 100 according to an embodiment of the present disclosure. Referring to FIG. 2, the VECSEL 100 includes a semiconductor chip 103 emitting a beam with a predetermined wavelength, a pump laser 105 supplying a pumping beam to the semiconductor chip 103, and an external mirror 120 that is disposed away from the semiconductor chip 103 and reflects the emitted beam back to the semiconductor chip 103. It should be understood that the semiconductor chip 103 can be of any suitable material, including by not limited to Si, GaAs, sapphire, etc.

A second harmonic generation (SHG) device 115 is disposed between the semiconductor chip 103 and the external mirror 120 to convert the wavelength of the beam emitted from the semiconductor chip 103. For example, the SHG device 115 converts a beam in the infrared ray range emitted from the semiconductor chip 103 to a beam in the visible light range. A semiconductor filter 110 is coupled with the SHG filter 115 having a high wavelength selectivity in order to increase the light conversion efficiency. The semiconductor filter 110 may be disposed below the SHG device 115 so that the beam emitted from the semiconductor chip 103 is filtered before entering the SHG device 115, but can also be above the SHG device 115 to filter light emitted from the SHG device 115.

An alternative to the semiconductor filter 110 can be a dielectric filter 110 and the dielectric filter 110 may also be formed on or under the SHG device 115.

The semiconductor chip 103 includes an active layer 102 emitting a beam at a predetermined wavelength and a reflection layer 101 reflecting the beam to the outside of the active layer 102. As is well known in the art, the active layer 102 may include a quantum well layer and the quantum well layer has a resonant periodic gain (RPG) structure including barrier layers between a plurality of quantum wells in a typical configuration, although the invention is not limited thereto and any active layer structure will likely do. The active layer 102 absorbs the pumping beam emitted from the pump laser 105, and is thus excited to emit a beam. In order to obtain a gain, the quantum wells are respectively located at anti-nodes of a standing wave of a beam that is generated by the active layer 102 and resonates between the external mirror 120 and the reflection layer 101. The beam generated by the active layer 102 reciprocates between the external mirror 120 and the reflection layer 101 to be amplified.

To excite the active layer 102 with the pumping beam, the wavelength λ₁ of the pumping beam should be shorter than the wavelength λ₂ of the beam generated by the active layer 102. For example, when the active layer 102 emits a beam in the infrared ray within the range of 920 nm to 1060 nm, the wavelength λ₁ of the pumping beam may be approximately 808 nm. Since it is difficult to inject carriers uniformly into a large area by electric pumping, optical pumping is advantageous to obtain high output, although electrical pumping is nevertheless a possible alternative.

A lens 107 is disposed between the pump laser 105 and the semiconductor chip 103 to focus the pumping beam emitted from the pump laser 105.

The external mirror 120 is separated a predetermined distance from and faces the actives layer 102, reflects most of the beam that is emitted from the active layer 102 back to the active layer 102 for resonance, and transmits a portion of the beam amplified through resonance to the outside. A reflective surface of the external mirror 120 is concave such that the reflected beam can be converged onto the active layer 102.

The reflection layer 101 reflects the beam generated by the active layer 102 to the external mirror 120 so that beam can resonate between the external mirror 120 and the reflection layer 101. The reflection layer 101 may be a Distributed Bragg Reflector (DBR) which is designed to have maximum reflectivity at the wavelength λ₂ of the emitted beam. The reflection layer 101 can be formed by alternately stacking two types of semiconductor layers having different refractive indexes with a thickness of λ₂/4. For example, the DBR layer, which reflects the emitted beam and transmits the pumping beam, can be formed by repeatedly alternating an AlₓGa₍₁₋ₓ₎As layer and an Al_{y}Ga_{(1-y)}As layer (0≦x,y≦1, x≠y).

A heat sink 104 is formed under the semiconductor chip 103 in order to dissipate heat generated by the active layer 102.

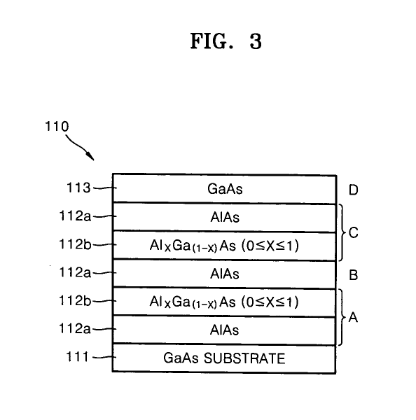

FIG. 3 is a cross-sectional view of the semiconductor filter 110. The semiconductor filter 110 is formed by alternately stacking a first semiconductor layer 112a having a relatively low refractive index and a second semiconductor layer 112b having a relatively high refractive index on a substrate 111. The semiconductor filter 110 can be easily manufactured through a semiconductor process. For example, the substrate 111 may be formed of GaAs, the first semiconductor layer 112a of AlAs, and the second semiconductor layer 112b of Al_{y}Ga_{(1-y)}As (0≦x≦1). The second semiconductor layer 112b may be formed of, for example, Al_{0.2}Ga_{0.8}As.

The semiconductor filter 110 may further include a top layer 113 formed of Al_{y}Ga_{(1-y)}As (0≦x≦1). The top layer 113 may be formed of, for example, GaAs. Also, a first pair layer A including the first semiconductor layer 112a and the second semiconductor layer 112b, a second pair layer B including a first semiconductor layer 112a, and a third pair layer C including the first semiconductor layer 112a and the second semiconductor layer 112b can be repeated from 1 to 100 times. The semiconductor filter 110 has a transmittance of 30% at a predetermined wavelength and a line width of 10 nm or less.

Each of the substrate 111 and the top layer 113 has a non-zero thickness of less than or equal to 10 nm, and the first semiconductor layer 112a and the second semiconductor layer 112b may have a thickness of one fourth of the wavelength of the beam emitted from the active layer 102.

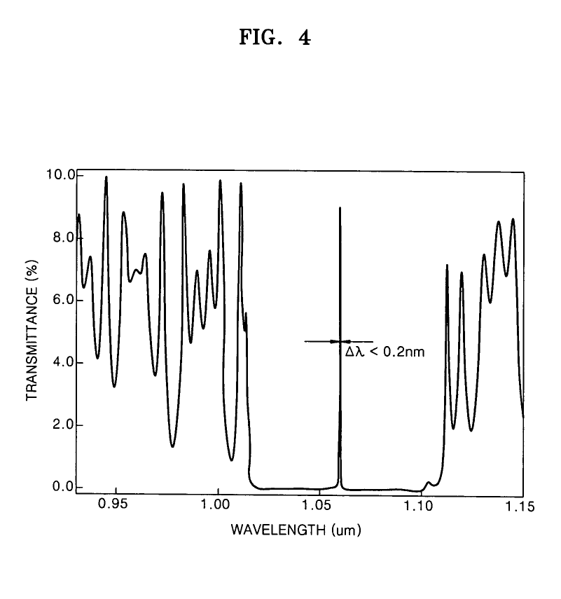

The semiconductor filter 110 illustrated in FIG. 3 transmits light with a wavelength of 1064 nm, and such light is converted into green light with a wavelength of 532 nm when passing through the SHG device 115. FIG. 4 illustrates the transmittance of the semiconductor filter 110. The transmittance is 30% or greater at a wavelength of 1064 nm and the line width (λ₁) thereof is 0.2 nm or less.

As described above, in the present disclosure, a semiconductor filter can simplify the structure of the VECSEL and increase the light conversion efficiency of the SHG device. While the use of a semiconductor filter has been described above, the same effect is obtained using a dielectric filter which is formed by alternately stacking dielectric layers having different permittivities, instead of the semiconductor filter. The dielectric filter may have a transmittance of 30% or greater at a selected wavelength and the line width thereof may be 10 nm or less. The semiconductor filter may be coupled with and disposed below the SHG device, while the dielectric filter may be formed on or under the SHG device. In certain embodiments, the semiconductor could be disposed above the SHG device.

As described above, the VECSEL according to the present disclosure includes a semiconductor filter or a dielectric filter which can easily select a wavelength to increase the light conversion efficiency and be easily manufactured to simplify the laser. Also, since the filter is coupled with the SHG device, no jig is needed during assembly, and thus the volume and manufacturing costs of the VECSEL can be reduced. In addition, no additional apparatus for controlling temperature is needed.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A vertical external cavity surface emitting laser (VECSEL) comprising:
a semiconductor chip including an active layer emitting a beam having a predetermined wavelength and a reflection layer reflecting the beam generated from the active layer to the outside of the active layer;
an external mirror that faces the active layer and repeatedly reflects a beam emitted from the active layer to the reflection layer to amplify the beam and output the amplified beam to the outside;
a pump device supplying energy to excite the active layer;
a second harmonic generation (SHG) device that is disposed between the semiconductor chip and the external mirror and converts the wavelength of the beam emitted from the active layer; and
a light wavelength filter coupled with the SHG device.

2. The VECSEL of claim 1, wherein the reflection layer is a multi-layered Distributed Bragg Reflector comprising sets of two semiconductor layers having different refractive indexes that are repeatedly alternately stacked.

3. The VECSEL of claim 2, wherein the thickness of each of the semiconductor layers is one fourth of the wavelength of the emitted beam.

4. The VECSEL of claim 1, wherein the active layer includes a plurality of quantum well layers generating a beam and each of the quantum well layers is disposed in an anti-node of a standing wave that is generated by the beam resonating between the external mirror and the reflection mirror.

5. The VECSEL of claim 1, wherein the light wavelength filter is a semiconductor filter that has a transmittance of 30% or greater and a non-zero line width of 10 nm or less.

6. The VECSEL of claim 1, wherein the light wavelength filter is a semiconductor filter that comprises:
a substrate; and
first and second semiconductor layers having different refractive indexes repeatedly sequentially stacked on the substrate.

7. The VECSEL of claim 6, wherein the first semiconductor layer is an AlAs layer having a relatively low refractive index and the second semiconductor layer is an AlₓGa₍₁₋ₓ₎As layer (0≦x≦1) having a relatively high refractive index.

8. The VECSEL of claim 6, wherein the thickness of each of the first and second semiconductor layers is one fourth of the wavelength of the beam emitted from the active layer.

9. The VECSEL of claim 6, wherein the substrate has a non-zero thickness of 10 nm or less.

10. The VECSEL of claim 6, wherein the semiconductor filter includes a first pair layer including the first and second semiconductor layers stacked on the substrate, a second pair layer including the first semiconductor layer stacked on the first pair layer, and a third pair layer including the first and second semiconductor layer stacked on the second pair layer.

11. The VECSEL of claim 10, wherein the first, second, and third pair layers are repeated from 1 to 100 times.

12. The VECSEL of claim 6, wherein the semiconductor filter includes a top layer formed of AlₓGa₍₁₋ₓ₎As (0≦x≦1).

13. The VECSEL of claim 12, wherein the top layer has a non-zero thickness of 10 nm or less.

14. A VECSEL of claim 1, wherein the light wavelength filter is a semiconductor filter coupled with the SHG device.

15. A VECSEL of claim 1, wherein the light wavelength filter is a dielectric filter coupled with the SHG device .

16. The VECSEL of claim 15, wherein the dielectric filter has a transmittance of 30% or greater at a selected wavelength and a non-zero line width of 10 nm or less.

17. The VECSEL of claim 1, wherein the pump energy device is pump laser.

18. The VECSEL of claim 1, wherein the pump energy device is electrical pump supplying an electrical pumping energy.
